(19) United States
(12) Patent Application Publication
(10) Pub. No.: US 2014/0048897 A1
(43) Pub. Date: Feb. 20, 2014

(54) PIXEL WITH NEGATIVELY-CHARGED SHALLOW TRENCH ISOLATION (STI) LINER

(71) Applicants: Yin Qian, Milpitas, CA (US); Hsin-Chih Tai, San Jose, CA (US); Gang Chen, San Jose, CA (US); Duli Mao, Sunnyvale, CA (US); Vincent Venezia, Los Gatos, CA (US); Howard E. Rhodes, San Martin, CA (US)

(72) Inventors: Yin Qian, Milpitas, CA (US); Hsin-Chih Tai, San Jose, CA (US); Gang Chen, San Jose, CA (US); Duli Mao, Sunnyvale, CA (US); Vincent Venezia, Los Gatos, CA (US); Howard E. Rhodes, San Martin, CA (US)

(73) Assignee: OMNIVISION TECHNOLOGIES, INC., Santa Clara, CA (US)

(21) Appl. No.: 13/587,811

(22) Filed: Aug. 16, 2012

(51) Int. Cl. H01L 31/02; H01L 31/18

(52) U.S. Cl. 257/431; 438/57; 257/E31.11

(57) ABSTRACT

Embodiments of a pixel including a substrate having a front surface and a photosensitive region formed in or near the front surface of the substrate. An isolation trench is formed in the front surface of the substrate adjacent to the photosensitive region. The isolation trench includes a trench having a bottom and sidewalls, a passivation layer formed on the bottom and the sidewalls, and a filler to fill the portion of the trench not filled by the passivation layer.

### TECHNICAL FIELD

The present invention relates generally to image sensors and in particular, but not exclusively, to pixels including a shallow trench isolation (STI) including a liner.

### BACKGROUND

The trend in image sensors is to increase the number of pixels on the sensor, meaning that the pixels themselves are becoming smaller. In a typical image sensor, there are shallow trench isolations (STIs) adjacent to the photosensitive areas of each pixel. STIs are trenches whose purpose is to physically separate and electrically isolate adjacent pixels from each other, so that charge from one pixel does not migrate to an adjacent pixel and cause problems such as blooming. STIs can also be used to reduce dark current. Dark current is a small current that occurs in the absence of incident light. Dark current can be caused by material interfaces that have minute defects that generate charges (or electrons) that behave like signals even when no signal charges originate from photoelectric conversion of incident light.

Existing shallow trench isolations (STIs), however, have some shortcomings that decrease their effectiveness and make it difficult to reduce pixel size.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified. Drawings are not to scale unless otherwise indicated.

FIG. 1A is a schematic view of an embodiment of an image sensor.

FIG. 1B is a combination cross-sectional elevation and schematic of an embodiment of a pixel in an image sensor.

FIGS. 2A-2C are cross-sectional elevations of a substrate showing an embodiment of a process for forming a shallow trench isolation (STI) in the substrate.

FIGS. 3A-3E are cross-sectional elevations of a substrate illustrating an alternative embodiment of a process for forming a shallow trench isolation (STI) in the substrate.

FIG. 4 is a cross-sectional elevation of an alternative embodiment of shallow trench isolation.

FIGS. 5A-5B are cross-sections illustrating embodiments of cross-sectional trench shapes of shallow trench isolations.

FIG. 6 is a flowchart of an embodiment of a process for forming a pixel.

### DETAILED DESCRIPTION OF THE ILLUSTRATED EMBODIMENTS

Embodiments of a process and apparatus for a pixel including negatively-charged shallow trench isolation (STI) liners are described. Numerous specific details are described to provide a thorough understanding of embodiments of the invention, but one skilled in the relevant art will recognize that the invention can be practiced without one or more of the specific details, or with other methods, components, materials, etc. In some instances, well-known structures, materials, or operations are not shown or described in detail but are nonetheless encompassed within the scope of the invention.

Reference throughout this specification to “one embodiment” or “an embodiment” means that a particular feature, structure, or characteristic described in connection with the embodiment is included in at least one described embodiment. Thus, appearances of the phrases “in one embodiment” or “in an embodiment” in this specification do not necessarily all refer to the same embodiment. Furthermore, the particular features, structures, or characteristics may be combined in any suitable manner in one or more embodiments.

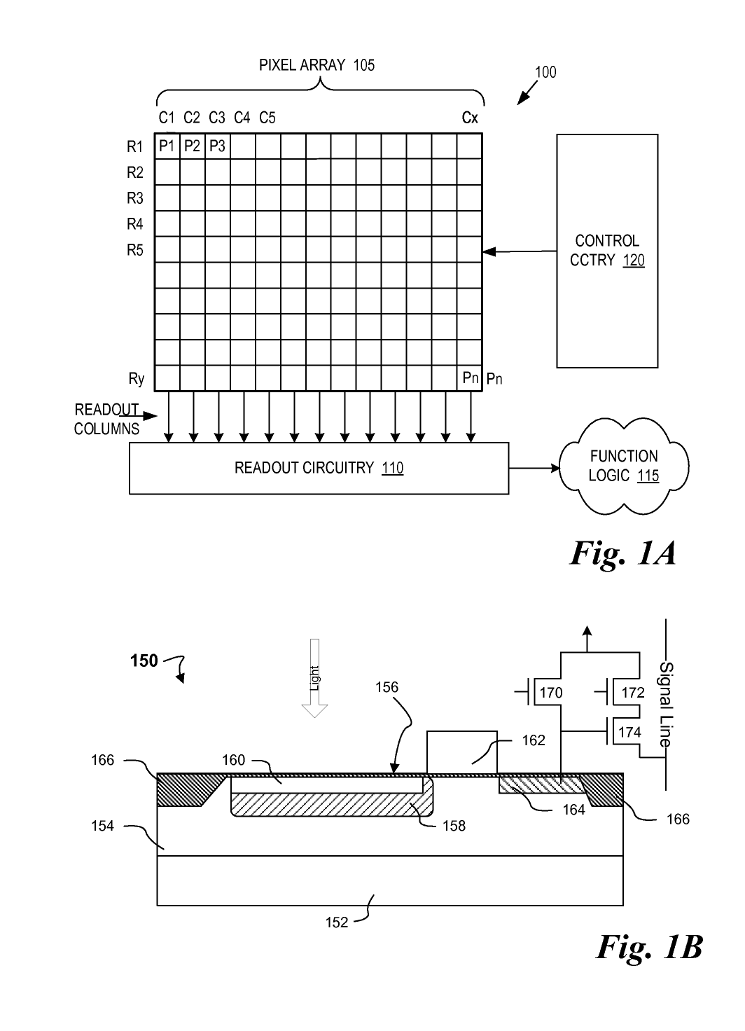

FIG. 1A illustrates an embodiment of an imaging system 100. Imaging system 100 includes a pixel array 105 having low crosstalk and high sensitivity, readout circuitry 110, function logic 115, and control circuitry 110.

Pixel array 105 is a two-dimensional (“2D”) array of image sensor elements or pixels (e.g., pixels P1, P2 . . . , Pn). In one embodiment, each pixel can be a front-side illuminated complementary metal-oxide-semiconductor (“CMOS”) imaging pixel. In embodiments of pixel array intended to capture color images, pixel array 105 can include a color filter pattern, such as a Bayer pattern or mosaic of red, green, and blue filters (e.g., RGB, RGBG or GRGB); a color filter pattern of cyan, magenta and yellow (e.g., CMY); a combination of both, or otherwise. As illustrated, the pixels in the pixel array are arranged into a rows (e.g., rows R1 to Ry) and columns (e.g., column C1 to Cx) to acquire image data of a person, place, or object, which can then be used to render a 2D image of the person, place, or object.

After each pixel has acquired its image data or image charge, the image data is read out by readout circuitry 110 and transferred to function logic 115. Readout circuitry 110 may include amplification circuitry, analog-to-digital (“ADC”) conversion circuitry, or otherwise. Function logic 115 may simply store the image data or even manipulate the image data via an image processor by applying post-image effects such as image compression, crop, rotate, remove red eye, adjust brightness, adjust contrast, or otherwise. In one embodiment, readout circuitry 110 may read out a row of image data at a time along readout column lines (illustrated) or may readout the image data using a variety of other techniques (not illustrated), such as a column readout, a serial readout, or a full parallel readout of all pixels simultaneously.

Control circuitry 110 is coupled to pixel array 105 to control operational characteristic of the array. For example, control circuitry 110 can generate a shutter signal for controlling image acquisition.

In one embodiment, the shutter signal can be a global shutter signal for simultaneously enabling all pixels within pixel array 105 to simultaneously capture their respective image data during a single acquisition window. In an alternative embodiment, the shutter signal is a rolling shutter signal whereby each row, column, or group of pixels is sequentially enabled during consecutive acquisition windows.

FIG. 1B illustrates an embodiment of a pixel 150, such as those that can be found in a pixel array such as pixel array 105 (see FIG. 1A). Pixel 150 is an active pixel that uses four transistors (known as a 4T active pixel), but in other embodiments pixel 150 could include more or less transistors. An epitaxial layer 154 is grown on a substrate 152, and pixel 150 is then formed in epitaxial layer 154. Pixel 150 includes a photodiode 156, a floating node or floating diffusion 164, and transfer gate 162 that transfers charge accumulated in photodiode 156 to floating node 164. Shallow trench isolations (STIs) 166 physically separate and electrically isolate pixel 150 from adjacent pixels in the pixel array and helps to reduce phenomena such as dark current.

In pixel 150, photodiode 156 includes a P-type region 160, sometimes known as a pinning layer, either at the surface or close to the surface of substrate 154. An N-type photosensitive region 158 abuts and at least partially surrounds P-type region 160. In operation, during an integration period (e.g., an exposure period or accumulation period) photodiode 156 receives incident light, as shown by the arrow in the figure and generates charge at the interface between P-type region 160 and N-type photosensitive region 158. The generated charge is held as free electrons in N-type photosensitive region 158. At the end of the integration period, the electrons held in N-type region 158 (i.e., the signal) are transferred into floating node 164 by applying a voltage pulse to transfer gate 162. When the signal has been transferred to floating node 164, transfer gate 162 is turned off again for the start of another integration period of photodiode 156.

After the signal has been transferred from N-type region 158 to floating node 164, the signal held in floating node 164 is used to modulate amplification transistor 174, which is also known as a source-follower transistor. Finally, address transistor 172 is used to address the pixel and to selectively read out the signal onto the signal line. After readout through the signal line, a reset transistor 170 resets floating node 164 to a reference voltage, which in one embodiment is V_{dd}.

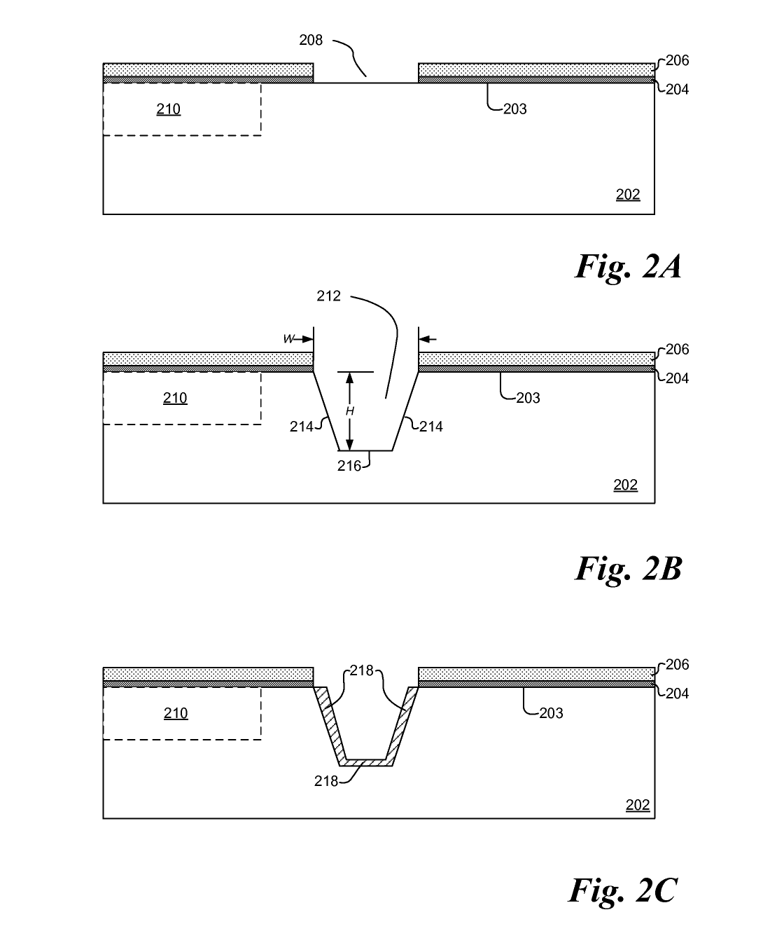

FIGS. 2A-2C illustrate an embodiment of a process for forming a shallow trench isolation (STI) such as STI 166 (see FIG. 1A). FIG. 2A illustrates initial part of the process, in which an oxide layer 204 is first deposited on front surface 203 of substrate 202 and a mask layer 206 is then deposited on oxide layer 204. In one embodiment, substrate 202 can be a p− doped (i.e., lightly doped with positively-charged dopants) epitaxial silicon layer, but in other embodiments other types of silicon and/or other types of doping can be used. Once deposited, both oxide layer 204 and mask layer 206 are photolithographically patterned and etched to form an opening 208 that exposes front surface 203.

FIG. 2B illustrates the next part of the process. Beginning with the condition illustrated in FIG. 2A, after opening 208 is formed to expose front surface 203, front surface 203 is etched using suitable etchants to form a trench 212 having sidewalls 214 and a bottom 216. Trench 212 has an overall width W and an overall depth H, giving it an aspect ratio of H/W. The etching that forms trench 212 can lead to certain damage and defects in sidewalls 214 and bottom 216 that can increase dark current in the pixel. Moderate- to low-dose implants done into the trench sidewalls before the trench is filled can also potentially cause damage and/or defects in the sidewalls. Examples of damage and defects that can occur in sidewalls 214 and bottom 216 include dangling bonds, crystal defects, and mechanical damage such as scratching.

FIG. 2C illustrates a next part of the process. Beginning with the state illustrated in FIG. 2B, a doped layer 218 is deposited along the sidewalls 214 and the bottom 216 of trench 212. In one embodiment doped layer 218 can be formed by depositing material on sidewalls 214 and bottom 216, but in other embodiments doped layer 218 can be formed by direct implantation of dopants into the sidewalls and bottom of the trench. In still other embodiments, doped layer can be formed using a combination of deposition and implantation. Doped layer 218 helps to cure some of the defects and damage created in sidewalls 214 and bottom 216 during etching of trench 212. In an embodiment in which substrate 202 is a P− layer (i.e., lightly doped with positive-charge dopants), doped layer 218 can be a P+ layer (i.e., highly doped with positive-charge dopants). Following the deposition along sidewalls 214 and bottom 216 of doped layer 218, the entire substrate is typically heated or annealed to allow dopants in doped layer 218 to diffuse into sidewalls 214 and bottom 216 into substrate 202. After heating or annealing, the remainder of trench 212—that is, the part of the trench not already filled by layer 218—is filled with another material, typically an oxide, to complete the STI.

The STI illustrated in FIGS. 2A-2C reduces dark current because doped layer 218 operates as a hole accumulation layer. Negative charges (electrons) arising from defects at the trench walls flow into doped layer 218 which, because it is a P+ layer, has a large concentration of holes into which the negative charges can disappear, preventing them from generating dark current. But the use of doped layer 218 has important shortcomings. Use of doped layer 218 results in a wide overall STI width W, leaving less chip “real estate” in which to form the remainder of the pixel. Moreover, dopants from doped layer 218 can diffuse into photodiode 210 during later heating or annealing. Diffusion of the dopants from doped layer 218 can cause lower full well capacity (FWC) in the photosensitive area. Finally, in high aspect ratio trenches, it can be difficult to provide uniform passivation along the trench sidewalls; generally the part of the sidewalls closest to the substrate surface will have higher passivation than the lower parts of the trench.

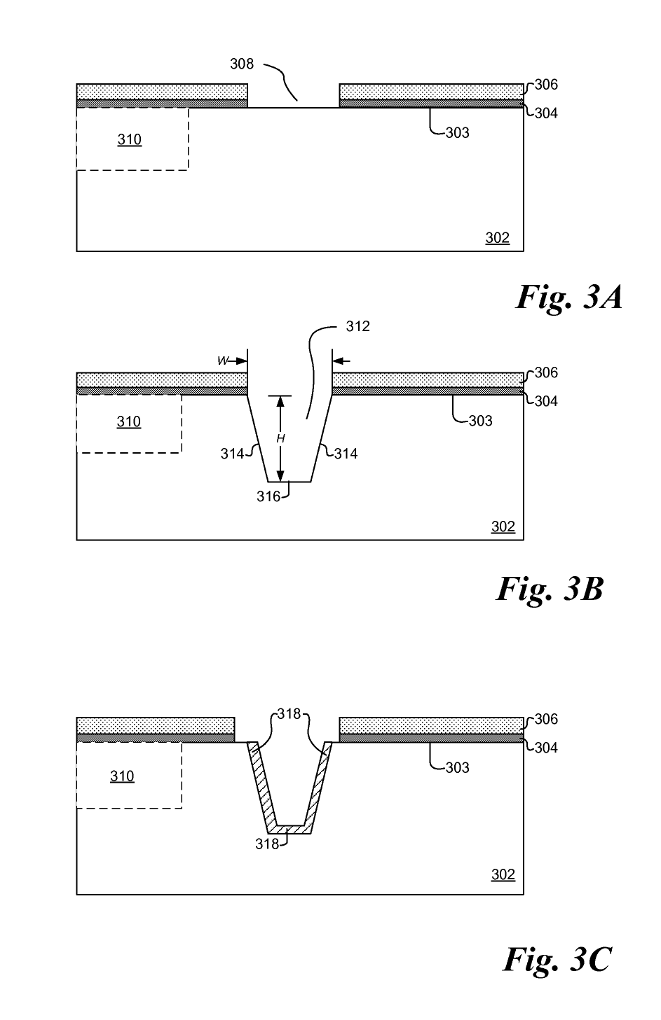

FIGS. 3A-3B illustrate an alternative embodiment of a process for forming a shallow trench isolation such as STI 166 in FIG. 1A. FIG. 3A illustrates an initial part of the process, in which an oxide layer 304 is first deposited or grown on front surface 303 of substrate 302 and a mask layer 306 is deposited on oxide layer 304. In one embodiment, substrate 302 can be P− doped (i.e., lightly doped with positively-charged dopants) epitaxial silicon layer, but in other embodiments other types of silicon and/or other types of doping, such as P+, N− or N+, can be used. In the illustrated embodiment, oxide layer 304 can be a silicon dioxide layer (Si02), but in other embodiments other types of insulators, including other types of oxides, can be used. Similarly, in the illustrated embodiment mask layer 306 can be photoresist, but in other embodiments mask layer 306 can be a harder mask such as a silicon nitride (SiN) mask.

Once deposited, both oxide layer 304 and mask layer 306 are photolithographically patterned and partially removed to form an opening 308 that exposes front surface 303 of substrate 302 so that the shallow trench isolation can be formed in substrate 302. Photosensitive region 310 is shown in dashed lines in the figure to give an idea of its position relative to the STI, but in most embodiments photosensitive region 310 is not formed until after one or more STIs are formed, for example as shown in FIG. 1A. The spacing between photosensitive area 310 and the STI is not shown to scale, and in different embodiments can differ from that shown. Other embodiments can also include intervening elements in between photosensitive area 310 and the STI.

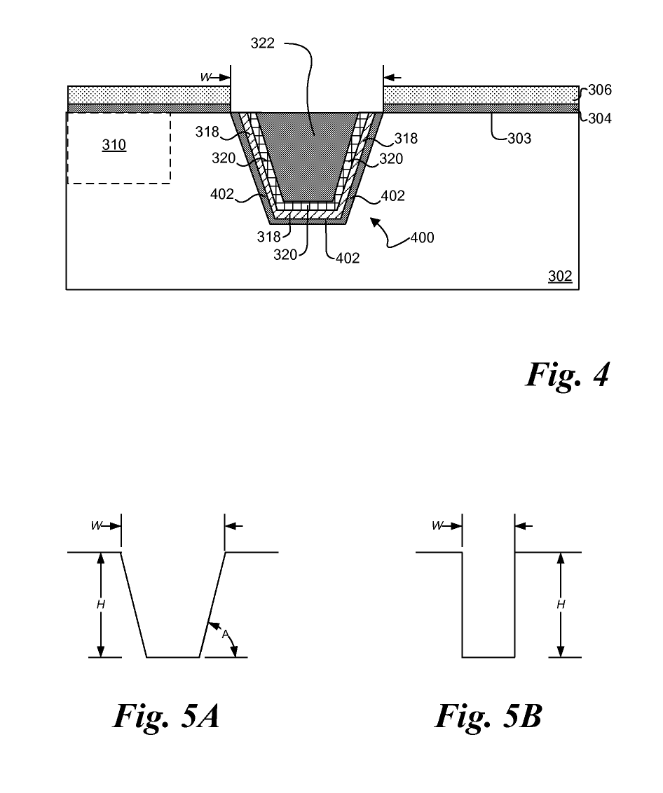

FIG. 3B illustrates a next step in the process. Beginning at the state illustrated in FIG. 3A, an etchant is applied to the exposed surface 303 of substrate 302 to form trench 312. Trench 312 includes a pair of sidewalls 314 and a bottom 316, and has an overall width W and overall depth H, giving it an aspect ratio of H/W. In the illustrated embodiment, the cross-sectional shape of trench 312 is trapezoidal but in other embodiments the cross-sectional shape of the trench 312 can be different (see FIGS. 5A-5B).

FIG. 3C illustrates a next step in the process. Beginning at the state illustrated in FIG. 3B, a passivation layer 318 is deposited on sidewalls 314 and bottom 316 of trench 312. Various techniques can be used to deposit passivation layer 318, including chemical vapor deposition (CVD), plasma enhanced chemical vapor deposition (PECVD), atomic layer deposition (ALD) or other suitable technique. ALD can be especially useful, because it provides excellent film quality and sidewall coverage. If a deposition method is used that deposits any passivation material outside trench 312 during formation of passivation layer 318, it can be removed from the field surrounding trench 312 using known techniques, such as etching with an etchant selective to the passivation layer material or other techniques such as chemical mechanical polishing (CMP).

In one embodiment, passivation layer 318 can be deposited such that it has a thickness along the sidewalls and along the bottom of between approximately 1 nanometers (nm) and 10 nm. A heating or annealing can be performed, if necessary, after passivation layer 318 is deposited on the trench sidewalls. In one embodiment, passivation layer 318 can be a dielectric with a negative fixed charged, such as aluminum oxide (nominally Al203), hafnium oxide (nominally Hf02), tantalum oxide (nominally Ta2O5), zirconium oxide (nominally ZrO2), titanium oxide (nominally TiO2), lanthanum oxide (nominally La2O3), praseodymium oxide (nominally Pr2O3), cerium oxide (nominally CeO2), neodymium oxide (nominally Nd2O3), promethium oxide (nominally Pm2O3), samarium oxide (nominally Sm2O3), europium oxide (nominally Eu2O3), gadolinium oxide (nominally Gd2O3), terbium oxide (nominally Tb2O3), dysprosium oxide (nominally Dy2O3), holmium oxide (nominally Ho2O3), erbium oxide (nominally ErO3), thulium oxide (nominally Tm2O3), ytterbium oxide (nominally Yb2O3), lutetium oxide (nominally Lu2O3), and yttrium oxide (nominally Y2O3), some combination thereof, or some other negatively charged dielectric not listed here.

In other embodiments, passivation layer 318 can be a pre-stressed layer. A pre-stressed embodiment of passivation layer 318 can be made by forming the layer in such a way that it retains residual stress after it is deposited on the sidewalls and bottom of the trench. In an embodiment with a pre-stressed passivation layer 318, the material of which the passivation layer is made can be a negatively charged dielectric, a positively-charged dielectric, or a neutral (i.e., neither positively nor negatively charged) dielectric. In different embodiments, the residual stress in the passivation layer can be compressive or tensile.

FIG. 3D illustrates a next step in the process. Beginning at the state shown in FIG. 3C, an insulating layer 320 is deposited on passivation layer 318. Insulating layer 320 can be deposited using the same techniques that are used to deposit passivation layer 318, such as atomic layer deposition (ALD). In one embodiment, insulating layer 320 can have a thickness similar to the thickness of passivation layer 318—on the order of 1-10 nm. In one embodiment, insulating layer 320 can be made of silicon dioxide (nominally Si02), but other embodiments can use other oxides, nitrides, or oxynitrides.

FIG. 3E illustrates a final part of the process. Beginning at the state shown in FIG. 3D, a filler 322, which in one embodiment can be an oxide, is deposited to fill the remainder of the trench—that is, the portion of trench 312 not already filled by passivation layer 318 and insulating layer 320. Filler 322 can be the same material used for insulating layer 320 in one embodiment, but in other embodiments filler 322 can be different material than insulating layer 320. In an embodiment in which insulating layer 320 filler 322 are the same material, filler 322 need not be deposited separately, but instead insulating layer 320 and filler 322 can be deposited in a single step to fill the remainder of trench 312 is not already filled by passivation layer 318. Put differently, if the insulating layer 320 and filler 322 are the same material, the separate deposit of insulating layer 320 can be skipped in favor of depositing only filler 322. At the conclusion of the oxide fill, the STI 350 is completed. One important advantage of an STI 350 produced according to this method is that it results in a smaller width W than is possible with current STI methods. A smaller width W results in more space available on the substrate for the formation of pixels and their supporting elements, meaning that more pixels can be formed on the substrate. This is because there is no need to dope the sidewalls to cure the defects/states since the negatively charged layer will cause a mirror positive charge to be present in the silicon which will essentially provide the same function as the P-type dopant layer 218 would.

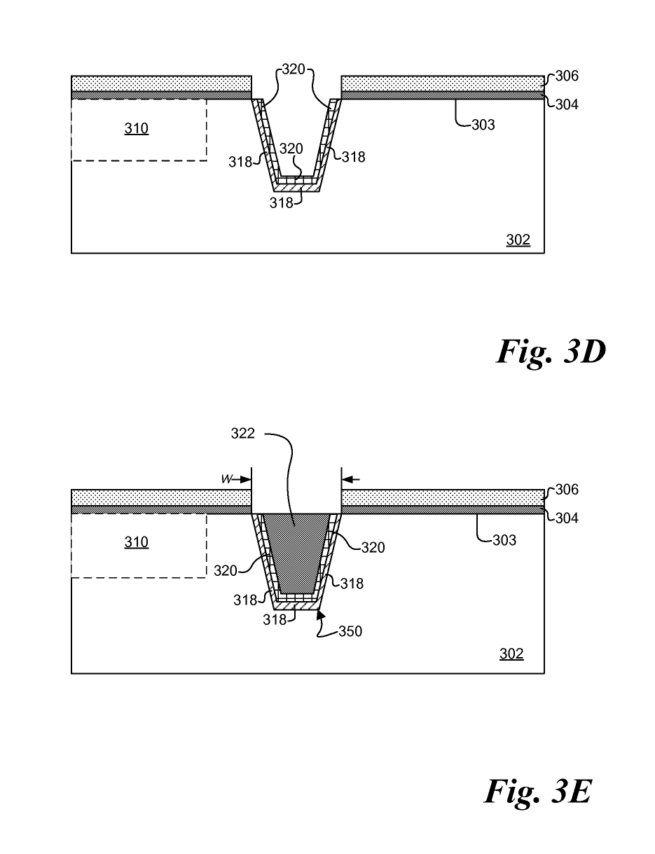

FIG. 4 illustrates an alternative embodiment of a shallow trench isolation (STI) 400. STI 400 is in most respects similar to STI 350 shown in FIG. 3E and is produced by substantially the same process. The primary difference between STI 400 and STI 350 is that STI 400 includes an additional thin oxide layer 402 interposed between passivation layer 318 and the walls 314 and bottom 316 of trench 312. Thin oxide layer 402 can have a thickness smaller than, or of the same order as, the thickness of passivation layer 318; generally, the thickness of additional oxide layer 402 should be small enough that it does not prevent passivation layer 318 from performing its function.

The process of forming STI 400 is in most respects similar to the process of forming STI 350, except that after formation of trench 312, as shown in FIG. 3B, thin oxide layer 402 is deposited on sidewalls 314 and bottom 316 of trench 312. In one embodiment, thin oxide layer 402 can be formed on the sidewalls and bottom by natural oxidation of the exposed sidewalls and bottom, for example by allowing the exposed sidewalls and bottom to remain in air or in an oxygen-rich environment after trench 312 is formed. In another embodiment, additional thin oxide layer 402 can a layer that is purposely deposited along the sidewalls and bottom using any of the techniques used to deposit the passivation layer, such as ALD.

FIGS. 5A-5B illustrate embodiments of cross-sectional shapes of trenches that can be used for STIs such as STI 350 or STI 400. FIG. 5A illustrates a trench having a trapezoidal cross-section of overall height H and overall width W, and sidewalls that are at an angle A relative to the bottom. Angle A can have a value that makes it an acute or obtuse angle. The quotient H/W is the aspect ratio of the trench, and in different embodiments the aspect ratio can be very low (i.e., a wide but shallow trench) to very high (a narrow and deep trench). FIG. 5B shows a trench with a cross-section that is rectangular instead of trapezoidal; the rectangular cross-sectional shape simply a special case of the trapezoidal cross-sectional shape in which angle A has a value of substantially 90°, such that the sidewalls are substantially perpendicular to the bottom. As with the trench shown in FIG. 5A, the ratio H/W is the aspect ratio of the trench, and in different embodiments the aspect ratio can be very low (i.e., a wide but shallow trench) to very high (a narrow and deep trench).

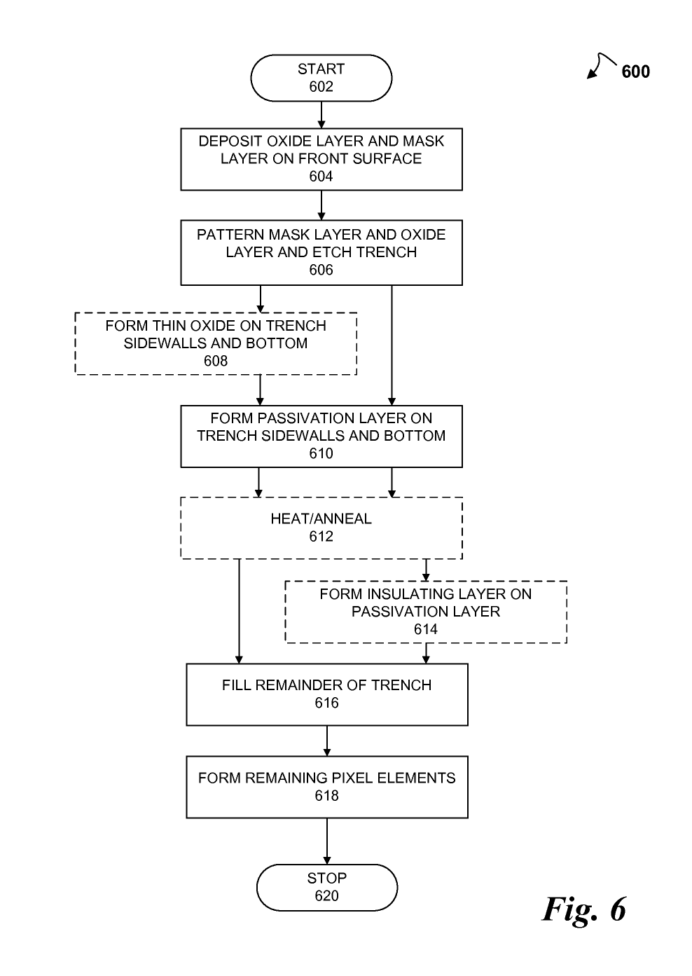

FIG. 6 illustrates an embodiment of a process for forming a pixel. In FIG. 6, certain blocks are surrounded by dashed lines, indicating that the activities described in those blocks can be used in some embodiments but need not be used in every embodiment. The process starts at block 602. At block 604 on oxide layer and a mask layer are deposited on a front surface of the substrate (see, e.g., FIG. 3A). At block 606 the mask layer and oxide layers are patterned and etched to expose the area of the front surface of the substrate where the trench will be formed, and the trench is then etched into the substrate (see, e.g., FIG. 3B).

Following block 606, process 600 proceeds to block 610, directly in one embodiment or via block 608 in another embodiment. In an embodiment the proceeds through block 608, at block 608 a thin oxide layer is formed on the trench sidewalls and bottom. The process then proceeds to block 610, where a passivation layer is formed on the thin oxide layer (see, e.g., FIG. 4). In an embodiment of process 600 that does not proceed through block 608, the process goes to directly from block 606 to block 610, where a passivation layer is formed directly on the sidewalls and bottom of the trench (see, e.g., FIG. 3C).

Following block 610, process 600 proceeds to block 616, directly in one embodiment or via one or both of blocks 612 and 614 in another embodiment. In an embodiment that proceeds directly to block 616, after the passivation layer is formed the remainder of the trench—that is, the portion of the trench not already occupied by the passivation layer—is filled with a filler such as an oxide at block 616. In an embodiment that proceeds to block 616 through block 612, the passivation layer is annealed at block 612 and the remainder of the trench—the portion of the trench not already occupied by the passivation layer—is filled with a filler such as an oxide at block 616. Finally, in an embodiment that proceeds from block 610 to block 616 through both blocks 612 and 614, after the passivation layer is deposited on the trench sidewalls and bottom at block 610 it is annealed at block 612. An insulating layer is formed on the passivation layer at block 614, and the remainder of the trench—that is, the portion of the trench not already occupied by the passivation layer and the insulating layer—is then filled with a filler such as an oxide at block 616 (see, e.g., FIG. 3D).

Following block 616, at block 618 the remaining pixel elements such as the photosensitive region, floating diffusion, pinning layers, transistor gates, and so on are formed on the substrate to complete a pixel and/or a complete image sensor.

The above description of illustrated embodiments of the invention, including what is described in the abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize. These modifications can be made to the invention in light of the above detailed description.

The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

1. A pixel comprising:
a substrate having a front surface;
a photosensitive region formed in or near the front surface of the substrate;
an isolation trench formed in the front surface of the substrate adjacent to the photosensitive region, the isolation trench comprising:
a trench formed in the front surface of the substrate, the trench including a bottom and sidewalls;
a passivation layer formed on the bottom and sidewalls;
a filler to fill the portion of the trench not filled by the passivation layer.

2. The pixel of claim 1 wherein the passivation layer is a dielectric with a fixed negative charge.

3. The pixel of claim 2 wherein the dielectric with a fixed negative charge is aluminum oxide (Al2O3), hafnium oxide (HfO2), tantalum oxide (TaO), or some combination thereof.

4. The pixel of claim 1 wherein the passivation layer is a pre-stressed passivation layer.

5. The pixel of claim 4 wherein the passivation layer is pre-stressed in tension.

6. The pixel of claim 4 wherein the pre-stressed passivation layer is a dielectric with a fixed negative charge.

7. The pixel of claim 1 wherein the passivation layer has a thickness between substantially 1 nanometer and 10 nanometers.

8. The pixel of claim 1, further comprising a thin oxide layer formed between the passivation layer and the sidewalls and bottom of the trench.

9. The pixel of claim 1 wherein the sidewalls of the trench are substantially normal to the bottom of the trench.

10. The pixel of claim 9 wherein the trench has a high ratio of depth to width.

11. The pixel of claim 1 wherein an oxide layer is formed between the filler and the passivation layer.

12. A method comprising:
forming a trench in a front surface of a substrate, the trench including sidewalls and a bottom;
forming a passivation layer on the sidewalls of the trench and on the bottom of the trench;
filling the portion of the trench not filled by the passivation layer.

13. The method of claim 12 wherein the passivation layer is formed by atomic layer deposition (ALD).

14. The method of claim 12 wherein the passivation layer is a dielectric with a fixed negative charge.

15. The method of claim 14 wherein the dielectric with a fixed negative charge is aluminum oxide (Al2O3), hafnium oxide (HfO2), tantalum oxide (TaO), or some combination thereof.

16. The method of claim 12, further comprising pre-stressing the passivation layer.

17. The method of claim 16 wherein pre-stressing the passivation layer comprised pre-stressing the passivation layer in tension.

18. The method of claim 12, further comprising forming a thin oxide layer between the passivation layer and the sides and bottom of the trench.

19. The method of claim 18 wherein the thin oxide layer is naturally formed by atmospheric oxidation.

20. The method of claim 12, further comprising forming a photosensitive region adjacent to the isolation trench on or near the front surface of the substrate.

21. The method of claim 12 wherein an oxide layer is formed between the filler and the passivation layer.
